(19) United States
(12) Patent Application Publication
(10) Pub. No.: US 2013/0313655 A1
(43) Pub. Date: Nov. 28, 2013

(54) SEMICONDUCTOR DEVICE AND A METHOD FOR MANUFACTURING THE SAME

(71) Applicants: Guilei Wang, Beijing (CN); Hushan Cui, Beijing (CN); Chao Zhao, Kessel-lo (BE)

(72) Inventors: Guilei Wang, Beijing (CN); Hushan Cui, Beijing (CN); Chao Zhao, Kessel-lo (BE)

(73) Assignee: Institute of Microelectronics, Chinese Academy Of Sciences, Beijing (CN)

(21) Appl. No.: 13/878,524

(22) PCT Filed: Jul. 18, 2012
(86) PCT No.: PCT/CN12/78780

§ 371 Date: Apr. 9, 2013

(30) Foreign Application Priority Data
May 23, 2012 (CN) 201210162593.2

(51) Int. Cl. H01L 29/78; H01L 29/66

(52) U.S. Cl. CPC H01L 29/7846; H01L 29/66553
USPC 257/402; 438/285

(57) ABSTRACT

A semiconductor device comprises a substrate; a shallow trench isolation embedded in the substrate and forms at least one opening region; a channel region located in the opening region; a gate stack including a gate dielectric layer and a gate electrode layer, located above said channel region; a source/drain region located on both sides of the channel region, including a stress layer which provides strain for the channel region. A liner layer is provided between the shallow trench isolation and the stress layer, which serves as a crystal seed layer of the stress layer. A liner layer and a pad oxide layer are provided between the substrate and the shallow trench isolation. The liner layer is inserted between the STI and the stress layer of the source/drain region as a crystal seed layer or nucleating layer for epitaxial growth, thereby eliminating the STI edge effect during the source/drain strain engineering.

### CROSS-REFERENCE TO RELATED PATENT APPLICATIONS

This application is a U.S. National Phase Application under 35 U.S.C. §371 of International Patent Application No. PCT/CN2012/078780, filed Jul. 18, 2012, and claims the benefit of Chinese Patent Application No. 201210162593.2, filed on May 23, 2012, titled “SEMICONDUCTOR DEVICE AND A METHOD FOR MANUFACTURING THE SAME,” all of which are incorporated by reference herein in its entirety.

### FIELD OF THE INVENTION

The present invention relates to a field of semiconductor devices. In particular, the present invention relates to a semiconductor device structure with an improved epitaxial edge and a method for manufacturing the same.

### BACKGROUND OF THE INVENTION

The method of cutting cost by only reducing the feature size has encountered a bottleneck, especially when the feature size decreases to less than 150 nm. In such a case, many physical parameters can not change in proportion, such as silicon band gap Eg, Fermi potential ωF, interface state and oxide layer charge Qox, thermal potential Vt, and the pn junction built-in potential, etc., which will affect the performance of a scaled-down device.

In order to further improve the device performance, stress would be introduced to an MOSFET channel for improving the mobility of charge carriers. For example, on a crystal chip with the crystal surface being (100), the crystal orientation of the channel region is <110>; in PMOSs, stress along the longitudinal axis (along the source/drain direction) is required to be pressure and stress along the transverse axis is required to be tension; in NMOSs, stress along the longitudinal axis is required to be tension and stress along the transverse axis is required to be pressure. That is, tension along the Source (referred to as S)—Drain (referred to as D) direction is introduced to the NMOS channel; pressure along the S-D direction is introduced to the PMOS channel. Conventional methods for applying compressive stress to the PMOS channel are epitaxially growing SiGe stress layers on the source/drain region along the S-D direction. Since the lattice constant of SiGe is greater than that of Si, the S/D stress layer will apply compressive stress to the channel therebetween. This increases hole mobility and thus increases driving current of PMOSs. Similarly, the epitaxial growth of a Si:C stress layer with a lattice constant smaller than that of Si on the source/drain region may provide tension for the NMOS channel.

However, since SiGe is selectively epitaxially grown on Si, different crystal surfaces have different epitaxial growth rates, for example, SiGe expitaxial growth on the (111) crystal surface is slowest. Therefore, epitaxial SiGe in the source/drain stress process integration has a larger edge effect.

FIGS. 1A-6C show a cross-sectional view of epitaxially growing SiGe on the source/drain region in the prior art.

First, as shown in FIGS. 1A and 1B, a shallow trench is formed by etching, FIG. 1A is a side sectional view of the device, FIG. 1B is a top view of the device, unless described otherwise, a FIG. A represents a side sectional view while a FIG. B represents a corresponding top view. A pad oxide layer or silicon nitride layer 2 is deposited on the substrate 1 and a shallow trench is etched through conventional mask exposure, wherein the substrate crystal surface is (100) and the crystal orientation of the channel region is <110>, the pad oxide layer or silicon nitride layer 2 is generally rectangular, which is corresponding to the active region and is surrounded by a shallow trench.

Second, as shown in FIGS. 2A and 2B, shallow trench isolation is formed by deposition. Oxides are filled in the shallow trench that is formed by etching, for example, silicon dioxide is generated by CVD deposition or thermal oxidation, and subsequently, the oxide layer is planarized by methods such as chemical mechanical polishing (CMP) until substrate 1 is exposed, thus forming a shallow trench isolation (STI) 3. Before oxides are introduced, an STI liner layer (not shown) can also be deposited in the shallow trench, the material being oxide or silicon nitride that is used as a stress liner layer of SiGe or SiC that is selectively epitaxially grown.

Again, as shown in FIGS. 3A and 3B, a gate stack structure is formed. A gate dielectric layer 4 is deposited on the substrate 1, the material of which can be silicon oxide or hafnium oxide of a high-k material, etc.; a gate electrode layer 5 is deposited on the gate dielectric layer 4, the material of which can be polysilicon or metal; a gate stack structure is formed by mask exposure etching; an insulating isolation layer such as silicon nitride is deposited on the entire structure and is then etched, only leaving an isolation spacer 6 around the gate stack structure.

Next, as shown in FIGS. 4A and 4B, a source/drain groove is formed by lithography, which is located inside STI3 and on both sides of the isolation spacer 6, corresponding to the source/drain region of PMOS to be formed later.

Then, as shown in FIGS. 5A, 5B and 5C, an SiGe stress layer 7 is epitaxially grown. Since the material of the STI liner layer is different from or dissimilar to that of the epitaxial layer 7, the STI liner layer cannot serve as crystal seed layer of the epitaxial layer 7, i.e., the lattice of SiGe or SiC layer that is epitaxially grown still does not match that of the liner and the STI3. Moreover, since the growth of SiGe on the (111) surface is slowest, a slanted side surface as shown in FIG. 5A would be formed at the edge of the STI3, i.e., at the interface of SiGe that is epitaxially grown, the side surface being a (111) surface. The gap formed by the side surface will reduce the compressive stress in the source/drain region SiGe, thus decreasing hole mobility and weakening the PMOS driving capability. FIG. 5C is a cross-sectional view of the structure of FIG. 5A along the BB′ direction perpendicular to the source/drain. Similarly, unless described otherwise, a FIG. C is a cross-sectional view of a corresponding structure along the BB′ direction perpendicular to the source/drain.

Finally, as shown in FIGS. 6A, 6B and 6C, a silicide is formed on the source/drain region. A metal such as Ni, Ti or Co is deposited on the SiGe stress layer 7 that is exitaxially grown, and then annealed to form a metal silicide, leaving a contact layer 8 on the SiGe stress layer 7 after unreacted metal is stripped.

According to FIGS. 6A, 6B and 6C, the thickness of SiGe is much thinner at the edge of the shallow trench isolation (STI). Thus, stress of SiGe along the longitudinal axis AA′ direction and the transverse axis BB′ in the source/drain region is reduced; the contact layer 8 of the silicide in the edge region may contact the silicon area at the bottom, which may increase the junction leakage current. Similar to PMOSs, SiC will also get thinner at the STI edge of NMOSs, thereby reducing driving capability.

In view of this, there is a need to provide a new semiconductor device that can effectively provide stress to enhance CMOS driving capability and reduce junction leakage current and a method of manufacturing the same.

### SUMMARY OF THE INVENTION

The object of the invention is to avoid the presence of gap between the stress layer of the semiconductor device and the shallow trench isolation which causes a reduced stress.

To this end, the present invention provides a semiconductor device, comprising: a substrate; a shallow trench isolation, embedded in said substrate and forming at least one opening region; a channel region, located in the opening region; a gate stack including a gate dielectric layer and a gate electrode layer, located above said channel region; a source/drain region, located on both sides of the channel region, including a stress layer which provides strain for the channel region; wherein there is a liner layer between the shallow trench isolation and the stress layer, which serves as a crystal seed layer of the stress layer; and, there are a liner layer and a pad oxide layer between the substrate and the shallow trench isolation.

For pMOSFETs, the stress layer comprises Si₁₋ₓGeₓ that is epitaxially grown; for nMOSFETs, the stress layer comprises Si_{1-y}C_{y} that is epitaxially grown, wherein both x and y are greater than 0 and less than 1.

The liner layer comprises Si₁₋ₓGeₓ, Si_{1-x-y}GeₓC_{y} or Si_{1-y}C_{y}, wherein both x and y are greater than 0 and less than 1; x is in the range of 0.15 to 0.7, and y is in the range of 0.002 to 0.02.

The liner layer has a thickness of 1-20 nm.

The stress region is at the same level as the top of the shallow trench isolation. The source/drain region further has a source/drain extension region located below the gate stack.

The present invention further provides a method of manufacturing a semiconductor device, including: forming a shallow trench in the substrate; forming a pad oxide layer and a liner layer at the bottom and on the side surfaces of the shallow trench successively, wherein the liner layer serves as a crystal seed layer of the stress layer; forming an isolation material in the shallow trench and on the liner layer to constitute a shallow trench isolation surrounding at least one opening region; forming a gate stack in the opening region; and forming a source/drain region on both sides of the gate stack, and a channel region between the source/drain regions below the gate stack, wherein the source/drain region comprises a stress layer providing strain for the channel region.

For pMOSFETs, the stress layer comprises Si₁₋ₓGeₓ that is epitaxially grown; for nMOSFETs, the stress layer comprises Si_{1-y}C_{y} that is epitaxially grown, wherein both x and y are greater than 0 and less than 1.

The liner layer comprises Si₁₋ₓGeₓ, Si_{1-x-y}GeₓC_{y} or Si_{1-y}C_{y}, wherein both x and y are greater than 0 and less than 1; x is in the range of 0.15 to 0.7, and y is in the range of 0.002 to 0.02.

The liner layer has a thickness of 1-20 nm.

The stress layer is at the same level as the top of the shallow trench isolation.

The isolation material is silicon dioxide.

The step of forming the source/drain region comprises: forming a source/drain groove in the substrate on both sides of the gate stack by etching under the protection of a mask; forming a side groove by laterally etching the substrate below the gate stack; removing the pad oxide layer on the side surfaces of the source/drain groove and the mask on the top of the source/drain groove to expose the liner layer; and epitaxially growing the stress layer in the source/drain groove to connect with the liner layer.

The source and drain groove is formed by dry etching.

The side groove is corroded by TMAH wet etching.

The present invention inserts a liner layer having an identical or similar material to the stress layer of the source/drain region between the STI and the stress layer of the source/drain region as a crystal seed layer or nucleating layer for epitaxial growth, thereby eliminating the STI edge effect, i,e., eliminating the gap between the STI and the stress layer of the source/drain region, preventing the stress from decreasing, and improving the charge carrier mobility of the MOS device so as to enhance the driving capability of the device,

### BRIEF DESCRIPTION OF THE DRAWINGS

The technical solution of the present invention is described in detail with reference to figures, in which:

FIGS. 1A to 6C are cross-sectional views of the step of forming a stress layer of the MOS source/drain region in the prior art; and

FIGS. 7A to 13C are cross-sectional views of the steps of forming a stress layer of the MOS source/drain region with a liner layer in accordance with this invention.

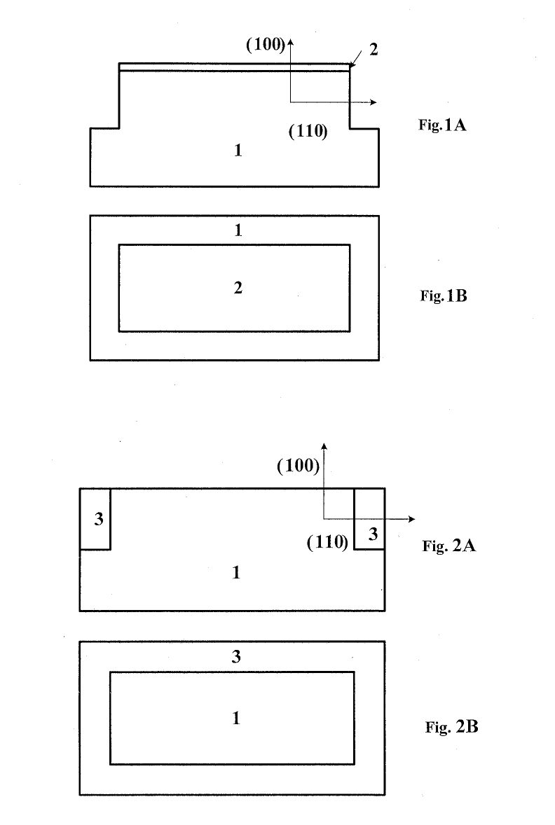

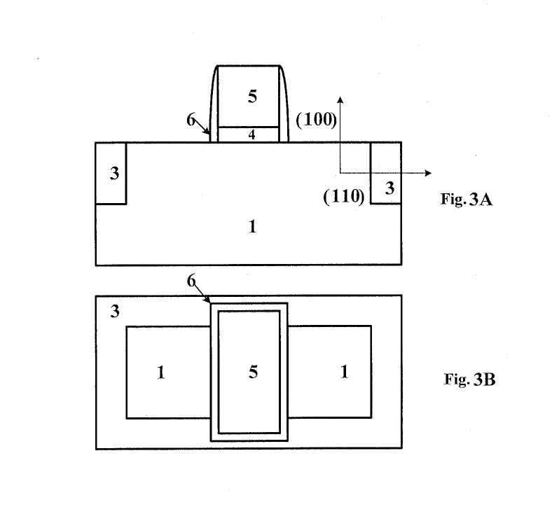

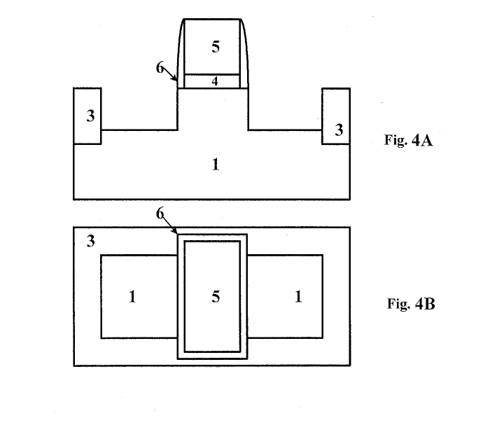

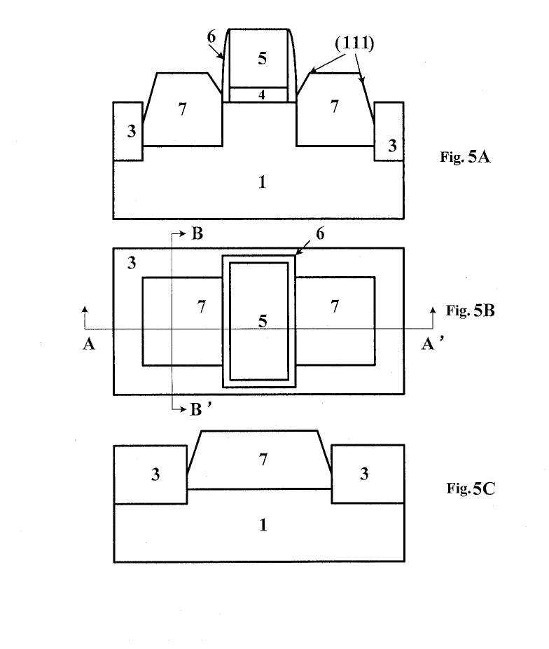

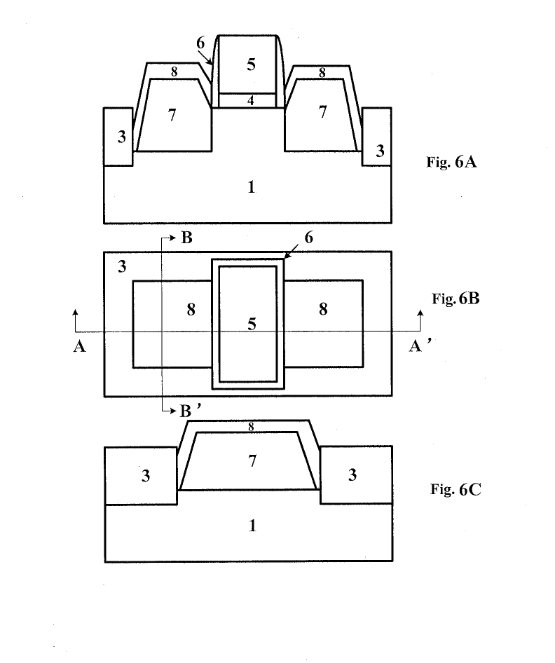

### DETAILED DESCRIPTION OF THE INVENTION

### Embodiments

Characteristics and technical effects of the technical solution of the present invention will be described in detail with reference to figures and in combination with illustrative embodiments. What needs to be noted is that similar reference signs refer to similar structures, but the terms “first”, “second”, “above”,“below”, “thick” and “thin” used in the present application can be used for modifying structures and method steps of various devices. These modifications, unless particularly described, do not indicate the space, order, or hierarchical relationship of the structures and method steps of the devices modified.

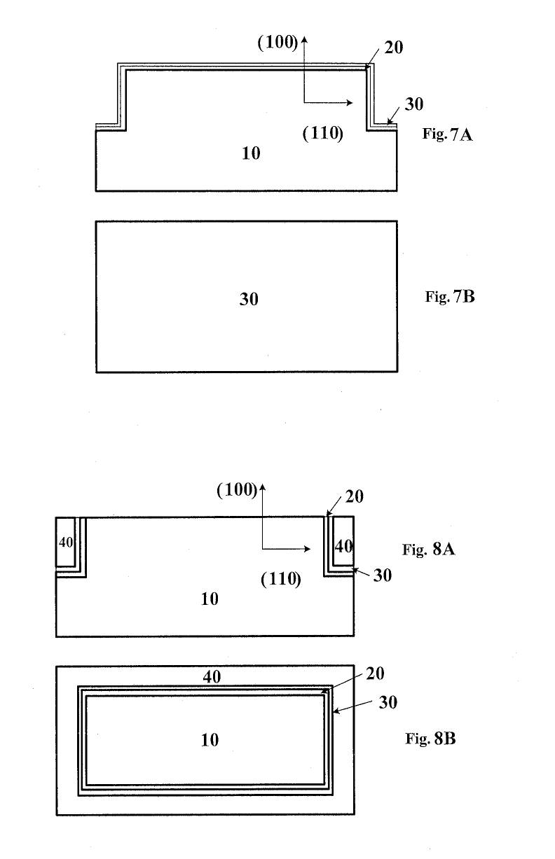

FIGS. 7A to 13C show cross-sectional views of SiGe that is epitaxially grown on the source/drain region in accordance with the present invention.

First, as shown in FIGS. 7A and 7B, a shallow trench surrounding one opening region (or an active region) is formed by etching the substrate 10 through conventional mask exposure, and then a pad oxide layer 20 is deposited on the substrate 10 and in the shallow trench. Among them, the substrate 10 can be bulk silicon or silicon on insulator (SOI), or a conventional semiconductor substrate material such as SiGe, SiC, sapphire, GaAs, InSb, or GaN. Preferably, the substrate 10 uses body silicon or SOI. The substrate crystal surface is (100) and the crystal orientation of the channel region is <110>. The pad oxide layer 20 completely covers the bottom surface and the side surfaces of the shallow trench as well as the surface of the active region of the substrate 10, its thickness being very thin, for example, only 5 nm or less. Then, a thin layer of a liner layer 30 is selectively epitaxially grown on the pad oxide layer 20 (since the pad oxide layer 20 is very thin, the semiconductor material deposited thereon can penetrate the pad oxide layer to react with or diffuse into the semiconductor material in the substrate so as to form a liner layer 30), the liner layer 30 and the pad oxide layer 20 being conformal, i.e., the liner layer 30 being completely covered on the pad oxide layer 20, thus being distributed at the bottom surface and side surfaces of the shallow trench as well as on the surface of the active region. The material of the liner layer 30 is Si₁₋ₓGeₓ, Si_{1-x-y}GeₓC_{y} or Si_{1-y}C_{y}, wherein both x and y are greater than 0 and less than 1, x is preferably in the range of 0.15 to 0.7, and y is preferably in the range of 0.002 to 0.02. For PMOSs, the liner layer 30 is preferably Si₁₋ₓGeₓ whose material is the same as the stress layer of the PMOS source/drain region; for NMOSs, the liner layer 30 is preferably Si_{1-y}C_{y} whose material is the same as the stress layer of the NMOS source/drain region. The function of the liner layer 30 is to serve as a nucleating layer or crystal seed layer so as to completely fill the gap between the STI 40 and the stress layer of the source/drain region caused by slow growth of SiGe on the (111) crystal surface upon the subsequent epitaxial growth of a stress layer of the source/drain region. The thickness of the thin layer of the liner layer 30 is, for example, 1 to 20 nm.

Second, as shown in FIGS. 8A and 8B, the liner layer 30 and the pad oxide layer 20 on the top of the active region are removed and a shallow trench isolation (STI) 40 is formed by filling an insulating material in the shallow trench. The liner layer 30 and the pad oxide layer 20 on the top of the active region are removed by HF wet etching, plasma dry etching such as fluorine-based gas, or chemical mechanical polishing (CMP), leaving the liner layer 30 and the pad oxide layer 20 only in the shallow trench. Then, the shallow trench is filled with isolation materials which are oxides, for example, silicon dioxides are generated by CVD deposition or thermal oxidation, and subsequently the oxide layer is planarized by methods such as chemical mechanical polishing (CMP) until the substrate 10 is exposed, thus forming a shallow trench isolation STI 40. At this time, there is a double layer stack structure having a liner layer 30 and a pad oxide layer 20 between the STI 40 and the substrate 10, wherein the pad oxide layer 20 serves as a protective layer of the silicon stress crystal seed layer subsequently eroded by TMAH anisotropic wet etching.

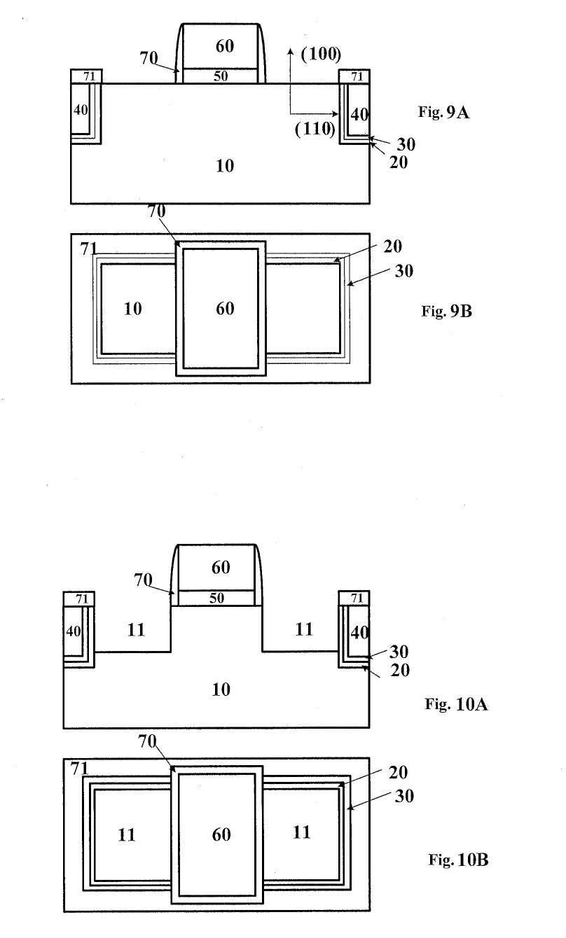

Once again, as shown in FIGS. 9A and 9B, a gate stack structure is formed on the active region. A gate dielectric layer 50 is deposited on the substrate 10, the material of which can be silicon oxide or hafnium oxide of a high-k material; a gate electrode layer 60 is deposited on the gate dielectric layer 50, the material being polysilicon or metal; a gate stack structure is formed by mask exposure etching; an insulating isolation layer such as silicon nitride is deposited on the entire structure and is then etched, leaving an isolation spacer 70 only around the gate stack structure.

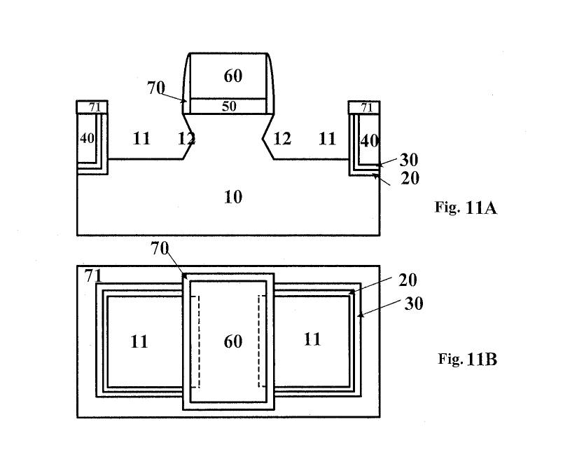

Then, as shown in FIGS. 10A and 10B, a source/drain groove 11 is formed by mask exposure and anisotropic etching, which is located inside the STI 40 and on both sides of the isolation spacer 70, corresponding to the source/drain region of PMOS/NMOS to be formed later. Preferably, the depth of the source/drain groove 11 is less than the thickness (or height) of the STI 40 so as to achieve good insulating isolation, Preferably, the source/drain groove 11 is formed by dry etching under the protection of SiO₂ or SiN mask (reference sign 71 as shown in the figure), e.g., by fluorine-based, chlorine-based or oxygen-based plasma etching. It is worth noting that during the process of forming a source/drain groove 11 by etching, part of the pad oxide layer 20 and the liner layer 30 between the STI 40 (sidewall) and the substrate 10 would be exposed to the side surfaces of the source/drain groove 11.

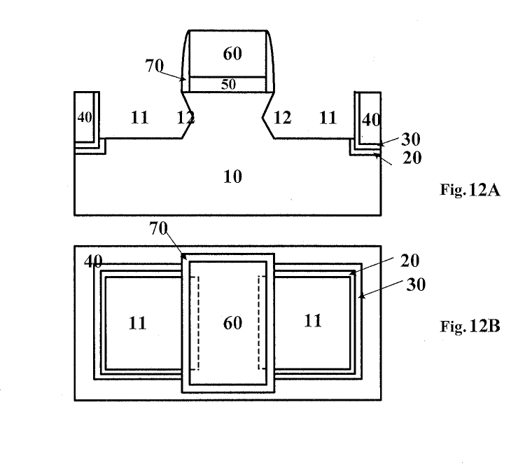

Then, as shown in FIGS. 11A and 11B, the source/drain groove 11 is laterally etched, resulting in the formation of a side groove 12 in the substrate below the gate stack structure 10. For example, the substrate 10 is anisotropically laterally corroded by using a TMAH wet etching liquid. At this point, due to the protection of the pad oxide layer 30, the liner layer 20 would not be etched. The side groove 12 is used for controlling the geometrical shape of the source/drain region, making part of the source/drain region to be formed in the future located below the gate stack structure and closer to the channel so as to constitute a source/drain extension region, thereby improving the device performance, for example, reducing the DIBL effect and avoiding the source-drain punch-through.

Next, as shown in FIGS. 12A and 12B, part of the pad oxide layer 20 and the mask 71 on the top exposed on the side surfaces of the source/drain groove 11 are removed such that part of the liner layer 30 is exposed in the source/drain groove 11. This is to make the source/drain region to be formed in the future directly adjoin the liner layer 30, thereby eliminating the STI edge effect, i.e., eliminating the gap between the STI and the stress layer of the source/drain region and preventing stress from decreasing.

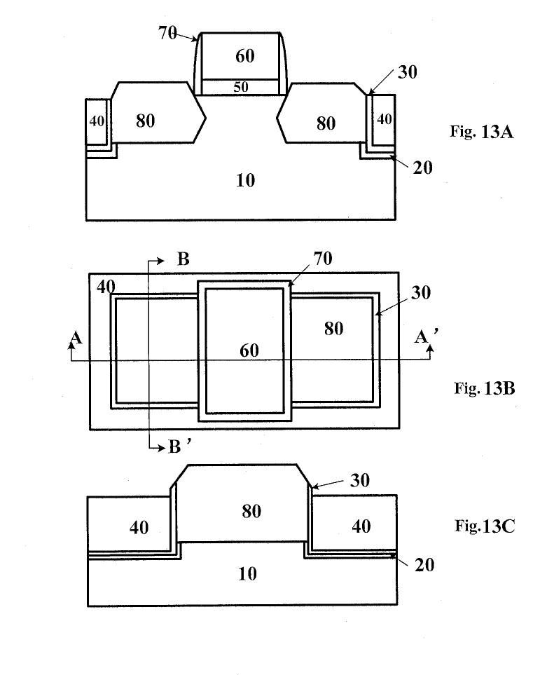

Finally, as shown in FIGS. 13A, 13B and 13C, a stress layer 80 is epitaxially grown to serve as a source/drain region of the device, i.e., the stress layer 80 serves as the source/drain region 80. As the material of the liner layer 30 is similar or identical to that of the stress layer 80, the gap that may probably exist is eliminated upon epitaxial growth, i.e., the STI edge effect is eliminated, thereby preventing stress from decreasing, maintaining or improving carrier mobility, and improving driving capability of MOS. In particular, the top surface of the stress layer 80 that is epitaxially grown is higher than that of the STI 40 as shown in FIG. 13A, but preferably, the top surface of the stress layer 80 is substantially at the same level as that of the STI 40 to prevent stress from leaking from the place where the stress layer 80 is higher than the STI 40 which reduces the stress actually applied, thereby preventing the driving capability from decreasing. For PMOSs, the stress layer 80 is preferably Si₁₋ₓGeₓ; for NMOSs, the stress layer 80 is preferably Si_{1-y}C_{y}, wherein both x and y are greater than 0 and less than 1, x is preferably in the range of 0.15 to 0.7, and y is preferably in the range of 0.002 to 0.02.

Finally, a silicide is formed on the stress layer 80 of the source/drain region. The depositing material on the stress layer 80 that is epitaxially grown is a metal of Ni, Ti or Co which is annealed to form a corresponding metal silicide, leaving a contact layer on the stress layer 80 (not shown in FIG. 13) after unreacted metal is stripped.

The device structure finally formed is as shown in FIGS. 13A, 13B and 13C: Shallow Trench Isolation (STI) 40 is located in the substrate 10 surrounded by a semiconductor opening region and the channel region of the device is located within the semiconductor opening region; the gate dielectric layer 50 is located above the channel region of the substrate 10, the gate electrode layer 60 is located on the gate dielectric layer 50, the gate dielectric layer 50 and the gate electrode layer 60 constitute a gate stack structure, and the isolating spacer 70 is located around the gate stack structure; the source/drain region 80 (i.e., the stress layer 80) is located on both sides of the gate stack structure and is composed of materials that can increase stress. For PMOSs, the stress layer 80 is preferably Si₁₋ₓGeₓ; for NMOSs, the stress layer 80 is preferably Si_{1-y}C_{y}, wherein both x and y are greater than 0 and less than 1; there is a liner layer 30 between the source/drain region 80 or stress layer 80 and the STI 40, the material of the liner layer 30 being identical or similar to that of the stress layer 80, such as Si₁₋ₓGeₓ Si_{1-x-y}GeₓC_{y} or Si_{1-y}C_{y}, wherein both x and y are greater than 0 and less than 1, x is preferably in the range of 0.15 to 0.7, and y is preferably in the range of 0.002 to 0.02; there are a liner layer 30 and a pad oxide layer 20 between the substrate 10 and the STI 40; the top of the stress layer 80 may further have a metal silicide (not shown). In particular, the top of the stress layer 80 is at the same level as the top of the STI 40.

The process of forming a stress layer 80 of the PMOS source/drain region is disclosed above. For NMOSs, the process steps are similar, and the only difference lies in that the material of the liner layer 30 becomes Si_{1-y}C_{y} so as to correspond to the source/drain stress layer 80 of SiC.

According to the present invention, a liner is inserted between the STI and the stress layer of the source/drain region as a crystal seed layer or nucleating layer for epitaxial growth, and the liner has an identical or similar material to the stress layer of the source/drain region, thereby eliminating the STI edge effect, i.e., eliminating the gap between STI and the stress layer of the source/drain region, thereby preventing stress from decreasing and improving carrier mobility of the MOS device so as to enhance driving capability of the device. The present invention has been described by referring to one or more exemplary embodiments, but it is known to those skilled in the art that various suitable changes and equivalent modes are made to the method of forming a device structure without departing from the scope of the present invention. In addition, may amendments that are suitable for specific situations or materials can be made according to the teachings disclosed without departing from the scope of the present invention. Therefore, the purpose of the present invention is not limited to the specific embodiments used for specific modes to carry out the present invention. But the device structure and the manufacturing method thereof disclosed will include all the embodiments that fall within the scope of the present invention.

1. A semiconductor device, comprising:
a substrate;
a shallow trench isolation, embedded in said substrate and forming at least one opening region;
a channel region, located in the opening region;
a gate stack including a gate dielectric layer and a gate electrode layer, located above said channel region;
a source/drain region, located on both sides of the channel region, including a stress layer which provides strain for the channel region;
wherein a liner layer is provided between the shallow trench isolation and the stress layer, said liner layer serving as a crystal seed layer of the stress layer; and
a liner layer and a pad oxide layer are provided between the substrate and the shallow trench isolation.

2. The semiconductor device according to claim 1, wherein for pMOSFETs, the stress layer comprises Si₁₋ₓGeₓ that is epitaxially grown; for nMOSFETs, the stress layer comprises Si_{1-y}C_{y} that is epitaxially grown,
wherein both x and y are greater than 0 and less than 1.

3. The semiconductor device according to claim 1, wherein the liner layer comprises Si₁₋ₓGeₓ, Si_{1-x-y}GeₓC_{y} or Si_{1-y}C_{y}, wherein both x and y are greater than 0 and less than 1.

4. The semiconductor device according to claim 1, wherein x is in the range of 0.15 to 0.7 and y is in the range of 0.002 to 0.02.

5. The semiconductor device according to claim 1, wherein the liner layer has a thickness of 1-20 nm.

6. The semiconductor device according to claim 1, wherein the stress region is at the same level as the top of the shallow trench isolation,

7. The semiconductor device according to claim 1, wherein the source/drain region further has a source/drain extension region located below the gate stack.

8. A method of manufacturing a semiconductor device, comprising the steps of:
forming a shallow trench in a substrate;
forming a pad oxide layer and a liner layer at the bottom and on the side surfaces of the shallow trench successively, wherein the liner layer serves as a crystal seed layer of the stress layer;
forming an isolation material in the shallow trench and on the liner layer to constitute a shallow trench isolation surrounding at least one opening region;
forming a gate stack in the opening region; and
forming a source/drain region on both sides of the gate stack, and a channel region between the source/drain regions below the gate stack, wherein the source/drain region comprises a stress layer providing strain for the channel region.

9. The method of manufacturing a semiconductor device according to claim 8, wherein for pMOSFETs, the stress layer comprises Si_{1-y}Geₓ that is epitaxially grown; for nMOSFETs, the stress layer comprises Si_{1-y}C_{y} that is epitaxially grown,
wherein both x and y are greater than 0 and less than 1.

10. The method of manufacturing a semiconductor device according to claim 8, wherein the liner layer comprises Si₁₋ₓGeₓ, Si_{1-x-y}GeₓC_{y} or Si_{1-y}C_{y}, where both x and y are greater than 0 and less than 1.

11. The method of manufacturing a semiconductor device according to claim 10, wherein x is in the range of 0.15 to 0.7, and y is in the range of 0.002 to 0.02.

12. The method of manufacturing a semiconductor device according to claim 8, wherein the liner layer has a thickness of 1-20 nm.

13. The method of manufacturing a semiconductor device according to claim 8, wherein the stress layer is at the same level as the top of the shallow trench isolation.

14. The method of manufacturing a semiconductor device according to claim 8, wherein the isolation material is silicon dioxide.

15. The method of manufacturing a semiconductor device according to claim 8, wherein the step of forming the source/drain region further comprises the sub-steps of:
forming a source/drain groove in the substrate on both sides of the gate stack by etching under the protection of a mask;
forming a side groove by laterally etching the substrate below the gate stack;
removing the pad oxide layer on the side surfaces of the source/drain groove and the mask on the top of the source/drain groove to expose the liner layer; and
epitaxially growing the stress layer in the source/drain groove to connect with the liner layer.

16. The method of manufacturing a semiconductor device according to claim 15, wherein the source and drain groove is dry etched.

17. The method of manufacturing a semiconductor device according to claim 15, wherein the side groove is corroded by TMAH wet etching.
